(19) United States
(12) Patent Application Publication
(10) Pub. No.: US 2024/0047203 A1
(43) Pub. Date: Feb. 8, 2024

(54) MONOLITHIC REMOTE EPITAXY OF COMPOUND SEMI CONDUCTORS AND 2D MATERIALS

(71) Applicant: Kyusang Lee, Charlottesville, VA (US)

(72) Inventor: Kyusang Lee, Charlottesville, VA (US)

(73) Assignee: Future Semiconductor Business, Inc, Charlottesville, VA (US)

(21) Appl. No.: 17/880,692

(22) Filed: Aug. 4, 2022

(51) Int. Cl. H01L 21/02

(52) U.S. Cl. CPC H01L 21/0254; H01L 21/0262; H01L 21/02595; H01L 21/02568

(57) ABSTRACT

Amorphous, polycrystalline, or single crystal 2D material interlayers are directly grown on the surface of bulk compound semiconductors (III-Nitride, III-V, II-VI, SiC, Silicon, Sapphire, complex oxides, or other oxides, etc) substrate or buffer layered substrates (III-Nitride, III-V, II-VI, SiC, Silicon nitride (SiN), complex oxides, or other oxides, etc), facilitating low contamination III-Nitride, III-V, II-VI, complex oxides, or other oxides epitaxial layer on templates without growth interruption through Molecular Beam Epitaxy (MBE), Metal Organic Chemical Vapor Deposition (MOCVD), Hydride Vapor Phase Epitaxy (HVPE), or other tools. This growth process reduces defects hindering the control of electronic properties of semiconductor epilayers, reduces processing time, and reduces materials cost by reusing the high-cost III-N, III-V, II-VI, SiC, Silicon nitride (SiN), complex oxides, or other oxides templates multiple times after the lift-off process.

### FIELD

The field of the present disclosure is directed to the fabrication of III-Nitrides and III-Nitride compound semiconductors.

### BACKGROUND

III-nitride semiconductors have become a cornerstone of modern electronic and optoelectronic devices. The nitrides of group III metal elements include aluminum nitride (AlN), gallium nitride (GaN), indium nitride (InN), boron nitride (BN) etc. and their alloys, all of which are compounds of nitrogen. III-nitride semiconductors crystallize in their most stable form into a wurtzite crystallographic structure with nitrogen atoms forming a hexagonal close packed (hcp) structure and the group III atoms occupying half of the tetrahedral sites available in the hcp lattice. III-nitrides are polar crystals as they do not have a center of symmetry.

High Electron Mobility Transistors (HEMTs) may be based on III-Nitrides or Gallium Arsenide (GaAs). III-Nitrides-based and GaAs-based HEMTs as well as pseudomorphic HEMTs (PHEMTs) are rapidly replacing conventional metal-semiconductor field-effect transistors (MESFETs) in applications requiring low noise figures and high gain. HEMTs are also known as MODFETs (modulation doped FET), TEGFETs (two-dimensional electron gas FET) and SDHTs (selectively doped heterojunction transistor). The main difference between HEMTs and MESFETs is the epitaxial layer structure. In the HEMT, compositionally different layers are grown in order to optimize and to extend the performance of the field effect transistor. III-V compound semiconductors are alloys containing elements from Group III (boron, aluminum, gallium, indium) and elements from Group V (nitrogen, phosphorus, arsenic, antimony, bismuth). The combination of elements from these groups may be binary (two elements, such as GaN or GaAs), ternary (three elements such as AlGaN or InGaAs), or quaternary (four elements such as AlGaInN or AlInGaP). III-V semiconductors using a Gallium Nitride (GaN) substrate are popular for optoelectronics, high power electronics, high frequency electronics, and other applications. For III-V semiconductors using a GaAs substrate, commonly used materials are Aluminum Gallium Arsenide AlₓGa₁₋ₓAs alloys (AlxGa1-xAs) and GaAs. PHEMTs also may incorporate Indium Gallium Arsenide InₓGa₁₋ₓAs alloys (InxGa1-xAs), but its different layers form heterojunctions because each layer has a different band gap. Structures grown with the same lattice constant but different band gaps are referred to as lattice-matched HEMTs. HEMT structures grown with slightly different lattice constants are called pseudomorphic HEMTs or PHEMTs. HEMTs and PHEMTs (collectively referred to as “HEMTs” in this disclosure) use II-V semiconductor materials. III-V semiconductor materials may be formed by epitaxial growth using metal-organic chemical vapor deposition (MOCVD) or molecular beam epitaxy (MBE).

III-V semiconductor compound materials may be grown by epitaxy, the growth of a crystalline material on a substate. Epitaxial growth of I-V semiconductor materials is a key technology, especially for the wireless, optical, and photovoltaic industries. PHEMTs are used extensively because they offer a high power added efficiency combined with excellent low noise figures and performance. PHEMTs, Heterojunction bipolar transistors (HBTs), and Vertical Cavity Surface Emitting Laser cells (VCSELs) require a pure, crystalline quality that epitaxial growth provides best. For III-V epitaxy, molecular beam epitaxy (MBE) is popular because MBE can control the thickness of the epitaxial layer to within monolayers.

III-V compound semiconductors, especially those based on gallium nitride (GaN), can also be formed by metal-organic chemical phase deposition (MOCVD). MOCVD is another highly complex process for growing crystalline structures. The MOCVD process deposits very thin layers of atoms onto a semiconductor wafer. MOCVD is often used to manufacture light-emitting diodes (LEDs), lasers, transistors, solar cells and other electronic and opto-electronic devices.

In the MOCVD process, reactant gases are introduced into the system at high pressure, such as about 1 torr. By contrast, the MBE process requires Ultra High Vacuum conditions (i.e., pressures below 10⁻⁸ Torr) for deposition.

Hydride Vapor Phase Epitaxy (HVPE) is an epitaxial growth technique that forms semiconductors such as gallium nitride GaN, gallium arsenide GaAs, indium phosphide InP and other related compounds, by reacting hydrogen chloride at an elevated temperature with group-III metals in order to produce gaseous metal chlorides. The gaseous metal chlorides are reacted with ammonia to produce III-Nitrides. The commonly used carrier gasses include, for example, ammonia, hydrogen, nitrogen and other chlorides.

Remote epitaxy is a technology that can effectively grow crystalline compound semiconductor epilayers using amorphous, polycrystalline, or single crystal 2D material interlayers without generating entailed dislocations. See. e.g., W. Kong, H. Li, K. Qiao, Y. Kim, K. Lee, Y. Nie, D. Lee, T. Osadchy, R. J. Molnar. D. K. Gaskill, R. L. Myers-Ward, K. M. Daniels, Y. Zhang, S. Sundram, Y. Yu, S-H. Bae, S. Rajan, Y. Shao-Horn, K. Cho, A. Ougazzaden, J. C. Grossman, and J. Kim, “Polarity governs atomic interaction through two-dimensional materials,” Nature Materials, vol. 17, pp. 999-1004, 2018; Y. Kim, S. S. Cruz, K. Lee, B. O. Alawode, C. Choi. Y. Song. J. M. Johnson, C. Heidelberger. W. Kong, S. Choi, K. Qiao. I. Almansouri, E. A. Fitzgerald, J. Kong, A. M. Kolpak, J. Hwang, and J. Kim. “Remote epitaxy through graphene enables two-dimensional material-based layer transfer,” Nature, vol. 544, pp. 340-343, 2017; S. Bae, K. Lu, Y. Han, S Kim, K. Qiao, C. Choi, Y. Nie, H. Kim, H. Kum, P. Chen, W. Kong, B. Kang, C. Kim, J. Lee. Y. Back, J. Shim, J. Park, M. Joo, D. Muller. K. Lee, J. Kim. “Graphene-Assisted Spontaneous Relaxation Towards Dislocation-Free Heteroepitaxy,” Natura Nanotechnology, vol. 15, pp. 272-276, 2020.

Remote epitaxy can grow compound semiconductors (III-Nitrides, III-V, II-VI, complex oxides, or other oxides, etc) epilayers “remotely” on a two-dimensional (2D) materials coated crystalline substrate, such as GaN, GaAs and InP crystalline substrates coated with graphene or monolayer hexagonal boron nitride (h-BN), which is also referred to as “white graphene,” within a certain interspacing gap as long as the potential field from the substrate is strong enough to penetrate through the 2D material interlayers. See, e.g., W. Kong, H. Li, K. Qiao, Y. Kim, K. Lee, Y. Nie, D. Lee, T. Osadchy, R. J. Molnar, D. K. Gaskill, R. L. Myers-Ward, K. M. Daniels, Y. Zhang, S. Sundram, Y. Yu, S.-H. Bae, S. Rajan, Y. Shao-Horn, K. Cho, A. Ougazzaden, J. C. Grossman, and J. Kim, “Polarity governs atomic interaction through two-dimensional materials,” Nature Materials, vol. 17, pp. 999-1004, 2018. Therefore, this process facilitates fabrication of such an epi-structure on particular parent substrates towards integrated device application, overcoming the mechanical failures such as defects and cracks.

2D materials grown by chemical vapor deposition (CVD) etc. can be exfoliated from the substrate and subsequently transferred onto single crystalline III-N substrates including gallium nitride (GaN). See, e.g., Y. Kim, S. S. Cruz, K. Lee, B. O. Alawode, C. Choi, Y. Song, J. M. Johnson, C. Heidelberger, W. Kong, S. Choi, K. Qiao, I. Almansouri, E. A. Fitzgerald. J. Kong, A. M. Kolpak, J. Hwang, and J. Kim, “Remote epitaxy through graphene enables two-dimensional material-based layer transfer,” Nature, vol. 544, pp. 340-343, 2017. However, this ex-situ transfer involves extra chemical exposure of the surface to oxygen, polymer(s), solvent(s), and metal(s) in an atmospheric environment, which is unfavorable for achieving high quality epitaxy.

Remote epitaxy can reduce entailed mechanical failures such as dislocations and cracks through manipulating the lattice of compound semiconductors (III-N (such as GaN. AlN, InN, hexagonal BN (h-BN), or their alloys, etc), III-V (such as InP, AlP, GaP, InAs, GaAs, InSb, or their alloys, etc), II-VI (such as CdSe, CdS, CdTe, ZnSe, ZnS, ZnTe, or their alloys, etc), complex oxides (such as SrTiO₃, LaMnO₃, BaTiO₃, or BiFeO₃, etc), or other oxides (such as SnO₂, ZnO, WO₃, TiO₂, or SiO₂, etc)) epilayers during epitaxial growth. The III-N, III-V, II-VI, complex oxides, or other oxides epilayers can thus be fabricated on the amorphous, polycrystalline, or single crystal 2D material interlayers (such as graphene, h-BN, cubic BN (c-BN), amorphous BN (a-BN), polycrystalline BN (p-BN), MoSe₂, WSe₂, MoS₂, WS₂, CrO₂, CrS₂, VO₂, VS₂, or NbSe₂, etc) transferred single crystalline III-N, III-V, III-VI, complex oxides, or other oxides substrates. However, the undesirable exposure of surface from chemicals in atmospheric environment during transferring 2D interlayers can significantly damage and contaminate the 2D interlayers and thus leads to failure of achievement of high quality II-N, III-V, II-VI, complex oxides, or other oxides epitaxy and beneficial electronic properties of epilayers for manufacturing semiconductor devices. Therefore, there is a need for a method of growing high quality III-Nitride epitaxial layers without the extra chemical exposures that reduce the quality of the resulting surface of the III-Nitride epilayers.

### SUMMARY

The following presents a simplified summary in order to provide a basic understanding of one or more aspects of the improved method. This summary is not an extensive overview of the invention, is not intended to identify key or critical elements of the invention, is not intended to limit the order of process steps, and is not intended to delineate the scope of the invention. Rather, the primary purpose of the summary is to present some concepts of the invention in a simplified form as a prelude to a more detailed description that is presented later.

In the preferred embodiment, 2D material interlayers are directly grown on the surface of a III-Nitride and III-V layered common substrate or any bulk substrates that allow to form a III-Nitride and III-V, II-VI and complex oxide template, which reduces contamination in the surface of a III-Nitride epitaxial layer on a template without growth interruption via Molecular Beam Epitaxy (MBE), Metal Organic Chemical Vapor Deposition (MOCVD), Hydride Vapor Phase Epitaxy (HVPE), or other tools.

### BRIEF DESCRIPTION OF THE FIGURES

FIG. 1A. Cross-sectional view of common substrates such as bulk GaN, GaAs, InP, InAs, GaSb, sapphire, SiC etc.

FIG. 1B. Cross-sectional view of film structure having III-N, III-V, II-VI, SiC, complex oxides, or other oxides buffer layers on common substrates.

FIG. 2 is a cross-sectional view of film structure having directly grown amorphous, polycrystalline, or single crystal 2D material interlayers on bulk III-N, III-V, II-VI, SiC, silicon, sapphire, complex oxides substrate, or other buffer layered common substrates (III-N, III-V, II-VI, SiC, SiN, complex oxides, or other oxides templates on a host substrate such as Si, sapphire, etc.).

FIG. 3 is a cross-sectional view of film structure having III-N, III-V, II-VI, SiC, complex oxides, or other oxides epilayers on directly grown amorphous, polycrystalline, or single crystal 2D material interlayers on III-N, III-V, II-VI, SiC, SiN, complex oxides, or other oxides templates.

FIG. 4 is a graph showing a XRD scan of intensity (CPS unit) versus 20 degrees showing that GaN epilayer had been formed on directly grown 2D material (h-BN) interlayer.

FIG. 5 is an AFM image of the surface of GaN epilayer formed on directly grown 2D material (h-BN) interlayer.

FIG. 6 is a block flow diagram demonstrating an embodiment of a novel method for fabricating III-N, III-V, II-VI, SiC, complex oxides, or other oxides epilayers using direct growth of amorphous, polycrystalline, or single crystal 2D material interlayers and remote epitaxy.

FIG. 7A is a cross-sectional view of a film structure having metal stressor layers formed on an epilayer formed of III-N, III-V, II-VI, complex oxide, or other oxide.

FIG. 7B is a cross-sectional view of the 2D material interlayer(s) of FIG. 7A being lifted off the substrate by a 2DLT process after a thermal release tape is applied to the film structure of FIG. 7A.

FIG. 7C is a cross-sectional view of a film structure being formed when the film layers with metal stressor layers that were lifted off by the thermal release tape in FIG. 7B are transferred or placed onto a host substrate.

FIG. 7D is a cross-sectional view of the film structure of FIG. 7C after removal of the thermal release tape and then subsequent removal of the metal stressor layers.

FIG. 7E is a cross-sectional view of an example of a film structure of HEMTs that may use an exfoliated GaN epilayer.

FIG. 7F illustrates examples of device applications that may use the remote compound semiconductor epilayer made by the novel process that have been exfoliated.

### DETAILED DESCRIPTION OF THE EMBODIMENTS

One or more aspects of the present invention are described with reference to the following description and the accompanying drawings, wherein like reference numerals are generally utilized to refer to like elements throughout, and wherein the various structures are not necessarily drawn to scale. These are indicative, however, of but a few of the various ways in which the principles of the invention may be employed. Other objects, advantages and novel features of the invention will become apparent from the following detailed description of the invention when considered in conjunction with the drawings. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are shown in block diagram or not shown in detail to avoid obscuring the invention. The present invention is not limited by the illustrated ordering of acts or events, as some acts may occur in different orders and/or concurrently with other acts or events. Further, not all illustrated acts or events are required to implement a methodology in accordance with the present invention.

In the following description, for purposes of explanation, numerous specific details are set forth in order to provide a thorough understanding of one or more aspects of the present invention. It may be evident, however, to one skilled in the art that one or more aspects of the present invention may be practiced with a lesser degree of these specific details. While a particular feature of the invention may have been disclosed with respect to only one of several aspects of the implementations, such feature may be combined with one or more other features of other implementations as may be desired and advantageous for any given or particular application.

The present disclosure introduces the direct growth of amorphous, polycrystalline, or single crystal 2D material interlayers on the surface of compound semiconductors substrate (III-Nitride, III-V, II-VI, SiC, complex oxides, or other oxides, etc) and buffer layered common substrates (III-Nitride, SiC, SiN, III-V, II-VI, complex oxides, or other oxides, etc), thereby facilitating low contamination to contamination-free III-Nitride, III-V, II-VI, complex oxides, or other oxides epitaxial layer on templates without growth interruption through Molecular Beam Epitaxy (MBE), Metal Organic Chemical Vapor Deposition (MOCVD), Hydride Vapor Phase Epitaxy (HVPE), or other tools. This novel direct growth process reduces defects that hinder the control of electronic properties of semiconductor epilayers, reduces processing time, and reduces materials cost due to multiple utilizations of III-N, III-V, II-VI, SiC, SiN, complex oxides, or other oxides templates by repeating the growth and lift-off processes.

It is critical to improve the formation and growth of 2D interlayers to minimize the unfavorable impurities of their surface. At the same time, it is desirable for the novel method to facilitate the reduction of processing time, complexity, defects and materials cost and promote up-scaling for high-volume production.

Therefore, the present disclosure discloses the novel direct growth method of growing amorphous, polycrystalline, or single crystal 2D interlayers and compound semiconductors (III-Nitride, III-V, II-VI, SiC, complex oxides, or other oxides, etc) without growth interruption via Molecular Beam Epitaxy (MBE), Metal Organic Chemical Vapor Deposition (MOCVD), or Hydride Vapor Phase Epitaxy (HVPE), etc. Thus, the novel method is not limited to the surface size of 2D interlayers, unlike in conventional transferring methods of 2D interlayers.

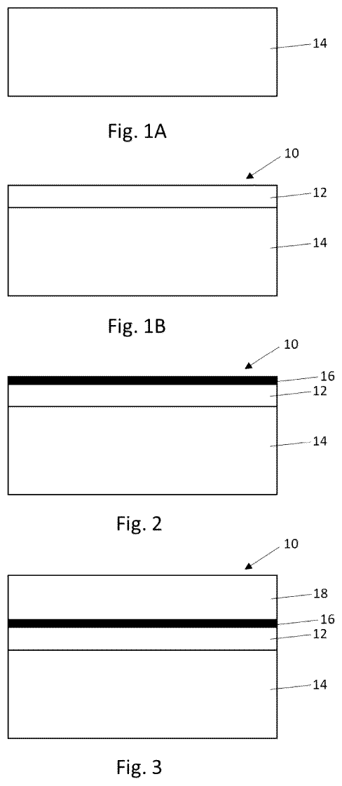

FIG. 1A is a cross-sectional view of bulk III-Nitride, III-V, II-VI, SiC, sapphire, SiN, a complex oxide(s), or other oxide(s) substrates 14 and FIG. 1B is a cross-sectional view of a film structure 10 having a buffer layer 12 formed of III-Nitride, III-V, II-VI, SiC, SiN, a complex oxide(s), or other oxide(s) on a common substrate 14. Optionally, the buffer layer 12 may be located on one or more intermediate layers which are on the common substrate 14. Thus, as used herein and as otherwise stated, “on” is defined to include both directly on and indirectly on. Thus, when a first layer is stated as being “on” a second layer, the first layer may be directly on the second layer or on an intermediate layer. Similarly, the common substrate may optionally be on other layers including a main substrate. Thus, as used herein, “substrate” may be the primary substrate or an intermediate layer. Buffer layer 12 may be a single layer or plural layers. Buffer layer 12 may comprise III-Nitride, III-V, II-VI, SiC, SiN, complex oxides, or other oxides, including, but not limited to, gallium nitride (GaN), aluminum nitride (AlN), indium nitride (InN), or hexagonal boron nitride (h-BN), or another suitable buffer layer. Likewise, the substrate 14 may be a single layer or plural layers. The substrate 14 may be GaN, AlN, GaAs, InP, InAs, GaSb, sapphire, silicon Si, silicon carbide SiC, silicon dioxide SiO₂, flexible molybdenum Mo, titanium Ti, tantalum Ta, copper Cu, hafnium Hf metal foils, or other substrates suitable for III-N, III-V, II-VI, complex oxides, or other oxide templates. To prepare the templates for substituting single crystalline substrates for III-Nitride compound semiconductors, the buffer layer 12 is formed on a common substrate through the use of a MBE, MOCVD or HVPE tool.

In the MBE growth technique, prior to growing the optional buffer layer 12, the substrate 14 is ex-situ cleaned by boiling in acetone and ethyl alcohol for 1 minute to 10 minutes and dried with flowing nitrogen gas before being loaded into the MBE system. In the MBE chamber, the substrate 14 is thermally outgassed in ultrahigh vacuum (UHV) at a temperature ranging from 500° C. to 1,000° C., inclusive, applied to the substrate for 1 hour to 5 hours, where the preferable temperature and time are 900° C. for two hours. The buffer layer 12 with a thickness in the range from 10 nm to 5 μm, inclusive, is grown at substrate temperatures employed for MBE growth of layers (600° C. to 900° C., inclusive). For example, MBE growth temperature in GaN is 700° C. The time duration for MBE growth depends on the desired thickness, as the MBE growth rate is about 1 μm per hour. As an example, if one wants to deposit one μm of III-N and III-V buffer layer, the required time duration is estimated to be one hour. The metal sources, such as gallium Ga, aluminum Al, indium In, or boron B, etc., are preferably provided with ingot type purity 6N to 7N. The nitrogen source is supplied with a nitrogen gas (N₂) radio frequency (RF) plasma unit through a mass flow controller.

In the MOCVD growth technique, the buffer layer 12 is grown using precursors with trimethylgallium (TMG), trimethylaluminum (TMA), trimethylindium (TMI), or triethylborane (TEB) and NH₃ with a carrier gas (H₂ or N₂) flow at substrate temperature in the range of 900° C. to 1,500° C., inclusive. For example, the MOCVD growth temperature in GaN is 1,100° C. The time duration depends on the desired thickness as the MOCVD growth rate in GaN is about two μm per hour. As an example, if one wants to deposit one μm of GaN buffer layer, the required time is estimated to be 30 minutes. A GaN buffer layer with a thickness in the range from 10 nm to 5 μm, inclusive, is grown as MBE. Therefore, the required time ranges from six minutes to 150 minutes.

An amorphous, polycrystalline, or single crystal 2D material interlayer 16 is directly grown on the optional buffer layer 12, or if no buffer layer 12 is formed, on the substrate templates as illustrated in FIG. 2. FIG. 2 is a cross-sectional view of the film structure 10 having a directly grown amorphous, polycrystalline, or single crystal 2D material interlayer(s) 16 on a buffer layer 12 on a common substrate 14. The 2D material interlayer 16 may be a single layer or plural layers. The 2D material interlayer 16 may comprise single crystalline, poly-crystalline, amorphous graphene, single crystalline, poly-crystalline, amorphous hexagonal boron nitride (h-BN), amorphous boron nitride (aBN), cubic boron nitride c-BN, graphene, molybdenum diselenium MoSe₂, tungsten diselenium WSe₂, molybdenum disulfur MoS₂, tungsten disulfur WS₂, chromium oxide CrO₂, chromium disulfur CrS₂, vanadium oxide VO₂, vanadium disulfur VS₂, or niobium diselenium NbSe₂, or other suitable 2D materials. Amorphous boron nitride is non-crystalline, while a stable crystalline form is hexagonal boron nitride, also called h-BN, α-BN, g-BN, and graphitic boron nitride. The 2D material interlayer 16 may be grown in a MBE or MOCVD chamber to a thickness ranging from, for example, 0.1 nm to 100 nm.

In the MBE growth technique, a graphene 2D material interlayer 16 may be grown using both gaseous and solid sources for carbon at substrate temperatures which are kept within the range between 1000° C. to 1200° C., inclusive, in order to provide the necessary mobility of carbon on the growth surface. A h-BN 2D material interlayer 16 may be grown through evaporating the boron ingot, preferably having purity 6N, as the group-III source by the electron-beam gun and flowing N₂ gas by a RF plasma source. The growth temperatures range from 500° C. to 1300° C., inclusive, as measured by a pyrometer. A MoSe₂ or WSe₂ 2D material interlayer 16 may be grown by generating a selenium (Se) flux by an effusion cell for Sc and generating either a molybdenum (Mo) flux or tungsten (W) flux by an electron-beam gun, at substrate temperatures ranging from 100° C. to 700° C., inclusive. For example, MBE growth temperature in MoSe₂ is 500° C. The required time depends on the desired thickness as the MBE growth rate in MoSe₂ is about 10 nm per hour. As an example, if one wants to deposit 20 nm, the required time is estimated to be two hours. Mo. W and Se ingots preferably have a purity of at least 6N. A MoS₂ or WS₂ 2D material interlayer 16 may be grown by generating a sulfur (S) flux by a valved sulfur cracker cell and generating either a Mo flux or W flux by an electron-beam gun, at substrate temperatures ranging from 100° C. to 900° C., inclusive. For example, the MBE growth temperature in MoS₂ is 800° C. The required time depends on the desired thickness as the MBE growth rate in MoS₂ is about 50 nm per hour. As an example, if one wants to deposit 20 nm, the required time is estimated to be 24 minutes. The S ingot preferably has purity of at least 6N.

In the MOCVD growth technique, a hexagonal boron nitride (hBN), amorphous boron nitride (aBN), MoSe₂ or WSe₂ 2D material interlayer 16 may be grown using precursors with trimethylBoron, molybdenum hexacarbonyl Mo(CO)ₑ or tungsten hexacarbonyl W(CO)₆ and dimethylselenium (CH₃)₂Se with a carrier gas including a hydrogen gas/nitrogen gas H₂/N₂ mixture flow at substrate temperatures ranging from 500° C. to 1,200° C., inclusive. For example, the MOCVD growth temperature in WSe₂ is 800° C. The required time depends on the desired thickness as the MOCVD growth rate in WSe₂ is about 10 nm per hour. As an example, if one wants to deposit 20 nm, the required time is estimated to be two hours. A MoS₂ or WS₂ 2D material interlayer 16 may be grown using precursors with M(NtBu)₂(dpamd)₂, where M is either Mo or W, and elemental sulfur (SR) with a carrier gas (such as N₂) flow at substrate temperatures ranging from 500° C. to 1,000° C., inclusive. For example, the MOCVD growth temperature in WS₂ is 800° C. The required time depends on the desired thickness as the MOCVD growth rate in WS₂ is about 100 nm per hour. As an example, if one wants to deposit 20 nm, the required time is estimated to be twelve minutes. As another example, a h-BN 2D material interlayer 16 may be grown through MOCVD at a growth temperature ranging from 700° C. to 1600° C., inclusive.

Finally, in the MBE growth technique, a semiconductor epilayer 18 can be grown on the 2D material interlayer 16 as shown in FIG. 3. FIG. 3 is a cross-sectional view of the film structure 10 having an epitaxial layer 18 comprising III-Nitride, III-V, II-VI, complex oxides, or other oxides on the directly grown amorphous, polycrystalline, or single crystal 2D material interlayer 16, which in turn, is on a substrate template 14 formed of III-Nitride, III-V, II-VI, SiC, SiN, complex oxides, or other oxides. The epitaxial layer 18 may be a single layer or plural layers. The epitaxial layer 18 may be GaN, AlN, InN, h-BN, or other suitable epitaxial layer. The MBE tool grows epilayers whose thickness ranges from 100 nm to 10 um, inclusive, at growth temperatures of 600° C. to 900° C., inclusive, similar to those used to form the GaN, AlN, InN, or h-BN buffer layer 12, under atmosphere in nitrogen gas N₂ RF plasma. For example, the MBE growth temperature in GaN is 700° C. The required time depends on the desired thickness as the MBE growth rate in GaN is about one μm per hour. As an example, if one wants to deposit 2 μm of GaN epilayer, the required time is estimated to be two hours.

The MOCVD growth technique grows the epilayer 18 at growth temperatures ranging from 900° C. to 1.500° C., inclusive, similar to those used to form the buffer layer 12 with precursors and a carrier gas (H₂) flow.

Furthermore, the formed GaN, AlN, InN, or h-BN epilayer 18 may comprise x composition incorporated in ternary alloys, including, but not limited to, AlₓGa₁₋ₓN, InₓGa₁₋ₓN, BₓGa₁₋ₓN, InₓAl₁₋ₓN, GaₓAl₁₋ₓN, BₓAl₁₋ₓN, AlₓIn₁₋ₓN, GaₓIn₁₋ₓN, and h-GaₓB₁₋ₓN, where 0<x<1).

The formed GaN, AlN, InN, or h-BN epilayer 18 may comprise x and y composition incorporated in quaternary alloys, including, but not limited to, AlₓIn_{y}Ga_{1-x-y}N, InₓGa_{y}Al_{1-x-y}N, AlₓGa_{y}In_{1-x-y}N, where 0<x<1 and 0<y<1.

The crystallinity of epilayers 18 grown on the 2D materials-coated substrates using these novel processes was examined to verify if the epilayers 18 read the crystalline registry of the underlying substrates through 2D materials. For methods of checking the crystallinity of epilayers, see, e.g., Y. Kim, S. S. Cruz, K. Lee, B. O. Alawode, C. Choi, Y. Song, J. M. Johnson, C. Heidelberger, W. Kong, S. Choi, K. Qiao, I. Almansouri, E. A. Fitzgerald, J. Kong, A. M. Kolpak, J. Hwang, and J. Kim, “Remote epitaxy through graphene enables two-dimensional material-based layer transfer,” Nature, vol. 544, pp. 340-343, 2017. The analysis revealed that all remoted epilayers 18 are single-crystalline with a crystalline orientation resembling that of the underlying substrates. These remoted epilayers 18 can be lifted off or exfoliated by 2D material based layer transfer (2DLT).

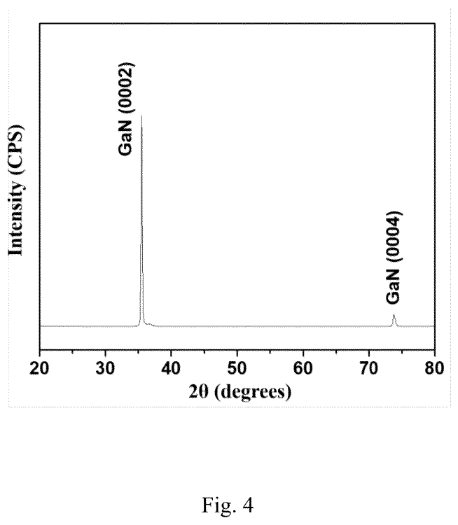

Referring to FIG. 4, X-ray diffraction (XRD) analysis was used to examine the structural quality, for example, of remoted GaN epilayers 18 by directly grown 2D material (h-BN) interlayer 16. The structural properties of the grown GaN epilayer are characterized by XRD operated with Cu-Ka radiation (l=1.540 Å). FIG. 4 is a XRD scan of intensity (CPS unit) versus 2θ degrees ranging from 20 degrees to 80 degrees, which shows that the GaN epilayer 18 has been formed on a directly grown 2D material (h-BN) interlayer 16. The as-deposited film shows (0001) oriented Wurtzite GaN characteristic peaks at about 35.7 degrees and 73.6 degrees due to the (0002) and (0004) diffractions of the Wurtzite GaN, respectively. The high order GaN (0002) diffraction peak confirms a good quality of the GaN films grown as an epitaxial structure.

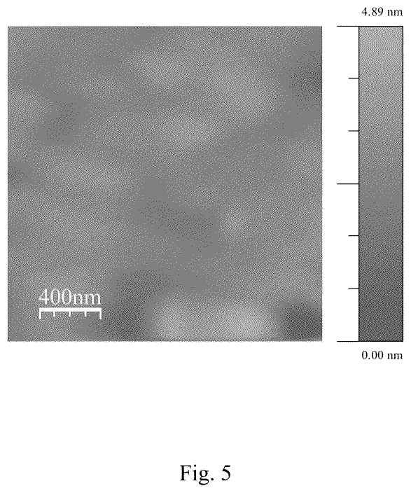

The surface quality of the resulting GaN epilayers was investigated by measuring the root mean square (RMS) roughness through Atomic Force Microscope (AFM). FIG. 5 is an AFM image of the surface of GaN epilayer 18 formed on a directly grown 2D material (h-BN) interlayer 16. The AFM image with a 2 um×2 um scan area demonstrates a RMS roughness and roughness average (Ra) values of 0.57 nm and 0.42 nm, respectively. The small RMS value of the scan shows that the surface is smooth on an atomic scale.

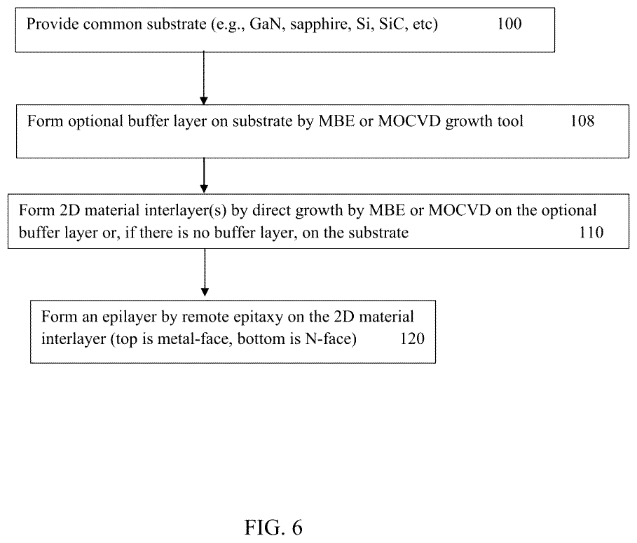

FIG. 6 is a block flow diagram demonstrating the novel method. This method may be used to directly grow amorphous, polycrystalline, or single crystal 2D material interlayers 16 on a substrate 14 and remotely fabricate epitaxial layers 18 formed of III-Nitride, III-V, II-VI, SiC, complex oxides, or other oxides on the directly grown 2D material interlayers 16. First, a substrate is provided in step 100. The substrate 14 may be bulk GaN, GaN templates on silicon or sapphire, AlN template on Si or sapphire, GaAs, InP, sapphire, Silicon nitride (SiN) template on sapphire, silicon Si, silicon carbide SiC, silicon dioxide SiO₂, flexible molybdenum Mo, titanium Ti, tantalum Ta, copper Cu, hafnium Hf metal foils, or other substrates suitable for III-N, III-V, II-VI, complex oxides, or other oxide templates. The substrate 14 is cleaned ex-situ and thermally outgassed under ultrahigh vacuum conditions, which are well known conditions and have been discussed previously in detail above.

In step 108, an optional II-Nitride buffer layer 12 may be formed on the substrate 14 by using a MBE or MOCVD growth tool, as previously described in detail above.

In step 110, a 2D material interlayer 16 is formed by direct growth onto the optional buffer layer 12, or if there is no buffer layer, on the substrate 14, using a MBE or MOCVD growth tool, as previously explained in detail above.

In step 120, a III-Nitride epitaxial layer 18 is remotely grown by remote epitaxy on the 2D material interlayer 16, as previously described in detail above. The epitaxial layer 18 may be exfoliated using the methods described in applicant's co-pending U.S. patent application titled “Fabrication of N-face III Nitrides by Remote Epitaxy.”

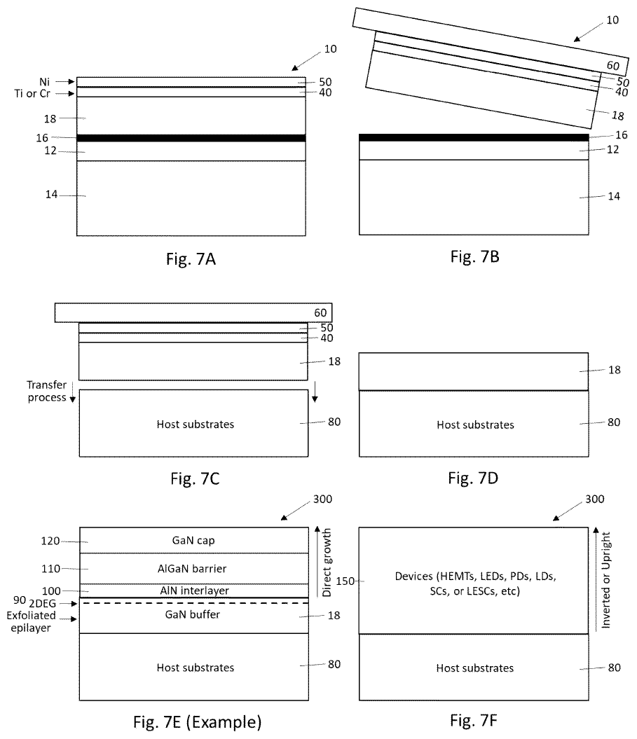

The exfoliated epilayers may be applied to form High-Electron-Mobility Transistors (HEMTs), Light-Emitting Diodes (LEDs), Photodiodes (PDs), Laser Diodes (LDs), Solar Cells (SCs), and Light-Emitting Solar Cells (LESCs) as shown in FIG. 7F. FIG. 7F illustrates examples of device applications that may use the remoted and exfoliated compound semiconductor epilayers made by the novel process.

FIGS. 7A to 7D illustrate cross-sectional views of an example embodiment of a film structure 10 made according to the methods disclosed in co-pending U.S. patent application titled “Fabrication of N-face III Nitrides by Remote Epitaxy.” Specifically, FIG. 7A is a cross-sectional view of a film structure 10 having metal stressor layers 40, 50 formed on an epilayer 18 formed of III-N, III-V, II-VI, a complex oxide(s), or other oxide(s), the epilayer 18 is on a directly grown amorphous, polycrystalline, or single crystal 2D material interlayer(s) 16 on a buffer layer 12 on a substrate 14. The 2D material interlayer 16 may be a single layer or plural layers. The 2D material interlayer 16 may comprise graphene, hexagonal boron nitride h-BN, amorphous boron nitride (aBN) and polycrystalline boron nitride, cubic boron nitride c-BN, molybdenum diselenium MoSe₂, tungsten diselenium WSe₂, molybdenum disulfur MoS₂, tungsten disulfur WS₂, chromium oxide CO₂, chromium disulfur CrS₂, vanadium oxide VO₂, vanadium disulfur VS₂, or niobium diselenium NbSe₂, or other suitable 2D materials. As described above for FIG. 2, the 2D material interlayer 16 may be grown in a MBE or MOCVD chamber to a thickness ranging from, for example, 0.1 nm to 100 nm. The metal stressor layers 40, 50 may be formed using the methods described with respect to FIG. 2A in co-pending U.S. patent application titled “Fabrication of N-face III Nitrides by Remote Epitaxy.”

FIG. 7B is a cross-sectional view of the compound semiconductors (III-Nitrides, III-V, II-VI, complex oxides, or other oxides), including the epitaxial layer 18, and metal stressor layers 40, 50 being lifted off the 2D material interlayer(s) 16 by a 2DLT process after a thermal release tape 60 is applied to the film structure 10 of FIG. 7A. The thermal tape 60 and its method of application are described in co-pending U.S. patent application titled “Fabrication of N-face III Nitrides by Remote Epitaxy” at, for example, the detailed description relating to FIG. 2B.

FIG. 7C is a cross-sectional view of a film structure 10 being formed when the film layer 18 and metal stressor layers 40, 50 that were lifted off by the thermal release tape 60 in FIG. 7B are transferred or placed onto a host substrate 80.

FIG. 7D is a cross-sectional view of the film structure 10 of FIG. 7C after the thermal release tape 80 is removed and then the metal stressor layers 40, 50 are removed in accordance with the methods described in, and illustrated in FIG. 3B and FIG. 3C of, co-pending U.S. patent application titled “Fabrication of N-face III Nitrides by Remote Epitaxy.”

An “upside-down” HEMT structure may be formed on the exfoliated epilayer 18, as explained with respect to FIG. 7E. “Upside-down HEMT” means that the film layers of the HEMT are formed in a reverse sequence so the resulting HEMT device is “upside down.” Alternatively, a traditional “right-side up” HEMT structure may be formed on the exfoliated epilayer 18, where the “right side up” HEMT structure comprises the same layers as the upside-down HEMT but formed in a reverse sequence.

FIG. 7E is a cross-sectional view of an example embodiment of a film structure of HEMTs that may use an exfoliated GaN epilayer. After the step shown in FIG. 7D, an aluminum nitride (AlN) interlayer 100 is directly grown on the GaN buffer layer 18. The dotted line refers to a conducting channel that arises from a combination of spontaneous and piezoelectric polarization at the interface of Al(Ga)N and GaN in the HEMT device. The label “2DEG” in FIG. 7E refers to a two-dimensional electron gas. The aluminum nitride interlayer 100 may be formed by MBE or MOCVD. Then an aluminum gallium nitride (AlGaN) barrier layer 110 is directly grown by any known method onto the AlN interlayer 100. For example, a MBE tool may be used to grow the AlN interlayer 110 whose thickness ranges from 1 nm to 10 nm at growth temperatures of 600° C. to 900° C. inclusive, with Al metal source under atmosphere in nitrogen gas N₂ RF plasma, similar to those used to form the GaN. Example) AlN thickness is 1 nm and growth temperature is 850° C. The MOCVD tool grows the AlN interlayer whose thickness ranges from 1 nm to 10 nm at growth temperatures ranging from 900° C. to 1,500° C., inclusive, with precursors (trimethylaluminum (TMA) and NH₃) and a carrier gas (H₂) flow, similar to those used to form the GaN. Example) AlN thickness is 1 nm and growth temperature is 1,200° C.

A gallium nitride cap layer 120 may be directly grown by any known method onto the AlGaN barrier layer 110. As an example, the GaN cap layer 120 may have a thickness in the range of about one nm to ten nm, the AlGaN barrier layer 110 may have a thickness in the range of about one nm to 100 nm (where AlxGa1-xN and x=0.26), the AlN interlayer 100 may have a thickness in the range of about one nm to ten nm, and the GaN buffer layer 18 may have a thickness in the range of about one μm to ten μm. The preferred example thicknesses for each layer are about three nm for the GaN cap layer 120, 25 nm for the AlGaN barrier layer 110, one nm for the AlN interlayer 100, and two μm for the GaN buffer layer 18.

As shown in FIG. 7F, device applications 300 may use the resulting film structure where semiconductor devices 150 may be formed by semiconductor processing in the film structure 300 on the substrate 80. Such device applications 300 include, for example, HEMTs. LEDs, photodiodes (PD), laser diodes (LD), solar cells (SC), light emitting semiconductor chips (LESC), and other devices.

While various embodiments of the present invention have been described above, it should be understood that they have been presented by way of example only and not by limitation. Further, although several embodiments of the present invention have been discussed, numerous additions, deletions, substitutions, and/or alterations to the invention may be readily suggested to one of skill in the art without departing from the scope of the appended claims. It is intended therefore that the appended claims encompass such additions, deletions, substitutions, and/or alterations. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents. Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In particular regard to the various functions performed by the above described components (assemblies, devices, circuits, etc.), the terms (including a reference to a “means”) used to describe such components are intended to correspond, unless otherwise indicated, to any component which per forms the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

I claim:

1. A method of fabricating a semiconductor device comprising the steps of:
providing a substrate;
directly growing a 2D material layer on the substrate; and
growing a semiconductor epitaxial layer on the 2D material layer.

2. The method of claim 1 further comprising:
forming a buffer layer on the substrate, the buffer layer including III-Nitride, III-V, II-VI, complex oxide; and
wherein the step of directly growing a 2D material layer grows the 2D material layer on the buffer layer.

3. The method of claim 1, wherein the epitaxial layer comprises III-Nitride, a III-V semiconductor, a II-VI semiconductor, a complex oxide, or an oxide.

4. The method of claim 1, wherein the epitaxial layer is a plurality of epitaxial layers.

5. The method of claim 1, wherein the epitaxial layer comprises gallium nitride, aluminum nitride, indium nitride, or hexagonal boron nitride.

6. The method of claim 1, wherein the epitaxial layer comprises a ternary alloy.

7. The method of claim 6, wherein the ternary alloy comprises AlₓGa₁₋ₓN, InₓGa₁₋ₓN, BₓGa₁₋ₓN, InₓAl₁₋ₓN, GaₓAl₁₋ₓN, BₓAl₁₋ₓN, AlₓIn₁₋ₓN, GaₓIn₁₋ₓN, or h-GaₓB₁₋ₓN, where 0<x<1.

8. The method of claim 1, wherein the epitaxial layer comprises a quaternary alloy.

9. The method of claim 8, wherein the quaternary alloy comprises AlₓIn_{y}Ga_{1-x-y}N, InₓGa_{y}Al_{1-x-y}N, or AlₓGa_{y}In_{1-x-y}N, where 0<x<1 and 0<y<1.

10. The method of claim 1, wherein the step of growing the semiconductor epitaxial layer on the 2D material layer includes using molecular beam epitaxy to grow the semiconductor epitaxial layer.

11. The method of claim 10, wherein the step of using molecular beam epitaxy to form the semiconductor epitaxial layer includes the steps of:
a. heating the substrate to a temperature between 500° C. to 900° C. inclusive;
b. flowing a nitrogen gas radio frequency plasma in the chamber; and
c. applying atmosphere pressure in the chamber.

12. The method of claim 11, wherein the temperature is approximately 700° C. and wherein the semiconductor epitaxial layer is gallium nitride.

13. The method of claim 1, wherein the step of growing forms the semiconductor epitaxial layer having a thickness ranging from 10 nm to 10 um inclusive.

14. The method of claim 1, wherein the step of growing the semiconductor epitaxial layer on the 2D material layer includes using metal oxide chemical vapor deposition to grow the semiconductor epitaxial layer.

15. The method of claim 14, wherein the step of using metal oxide chemical vapor deposition to form the semiconductor epitaxial layer includes the steps of flowing hydrogen gas in a chamber containing the substrate and heating the substrate to a temperature between 700° C. to 1,500° C. inclusive.

16. The method of claim 2, wherein the buffer layer comprises silicon carbide, a III-V semiconductor, a II-VI semiconductor, Sapphire, Silicon nitride (SiN), a III-Nitride semiconductor, a complex oxide, or an oxide.

17. The method of claim 2, wherein the buffer layer comprises gallium nitride, aluminum nitride, indium nitride, or hexagonal boron nitride.

18. The method of claim 1, wherein the step of growing uses molecular beam epitaxy to grow the 2D material layer.

19. The method of claim 1, wherein the step of growing uses metal organic chemical vapor deposition to grow the 2D material layer.

20. The method of claim 1, wherein the step of growing uses hydride vapor phase epitaxy to grow the 2D material layer.

21. The method of claim 1, wherein the 2D material layer is amorphous.

22. The method of claim 1, wherein the 2D material layer is polycrystalline.

23. The method of claim 1, wherein the 2D material layer is a single crystal material.

24. The method of claim 1, wherein the 2D material layer includes plurality of 2D material layers.

25. The method of claim 1, wherein the 2D material layer comprises graphene.

26. The method of claim 1, wherein the 2D material layer comprises hexagonal boron nitride (h-BN), amorphous boron nitride (aBN), polycrystalline boron nitride or cubic boron nitride c-BN.

27. The method of claim 1, wherein the 2D material layer comprises molybdenum diselenium MoSe₂, tungsten diselenium WSe₂, molybdenum disulfur MoS₂, tungsten disulfur WS₂, chromium oxide CrO₂, chromium disulfur CrS₂, vanadium oxide VO₂, vanadium disulfur VS₂, or niobium diselenium NbSe₂.

28. The method of claim 1, wherein the 2D material layer has a thickness in the range of 0.1 nm to 100 nm inclusive.

29. The method of claim 1, wherein the substrate includes plurality of layers.

30. The method of claim 1, wherein the substrate comprises sapphire, silicon, silicon carbide, silicon dioxide, molybdenum, titanium, tantalum, copper, or hafnium.

31. The method of claim 1, wherein the 2D material layer comprises hexagonal boron nitride and the step of directly growing the 2D material layer includes the steps of:
a. evaporating a boron ingot in a chamber containing the substrate by an electron beam;
b. flowing a nitrogen gas in the chamber with a radio frequency plasma source; and
c. heating the substrate to a temperature between 700° C. to 1300° C. inclusive.

32. The method of claim 1, wherein the 2D material layer comprises MoSe₂ or WSe₂ and the step of directly growing the 2D material layer includes the steps of:
a. generating a flux of selenium in a chamber containing the substrate;
b. generating a flux of molybdenum or tungsten in the chamber; and
c. heating the substrate to a temperature between 100° C. to 700° C. inclusive.

33. The method of claim 32, wherein the 2D material layer comprises MoSe₂ and the temperature is approximately 500° C.

34. The method of claim 1, wherein the 2D material layer comprises MoS₂ or WS₂ and the step of directly growing the 2D material layer includes the steps of:
a. generating a flux of sulfur in a chamber containing the substrate;
b. generating a flux of molybdenum or tungsten in the chamber; and
c. heating the substrate to a temperature between 100° C. to 900° C. inclusive.

35. The method of claim 34, wherein the 2D material layer comprises MoS₂ and the temperature is approximately 800° C.

36. The method of claim 1 wherein the 2D material layer comprises hexagonal boron nitride (h-BN), polycrystalline boron nitride (p-BN), cubic boron nitride (c-BN) or amorphous boron nitride (a-BN).

37. The method of claim 1, wherein the 2D material layer comprises MoSe₂ or WSe₂ and the step of using metal oxide chemical vapor deposition includes the steps of:
a. introducing molybdenum hexacarbonyl Mo(CO)₆ or tungsten hexacarbonyl W(CO)₆, into a chamber containing the substrate;
b. introducing dimethylselenium (CH₃)₂Se into the chamber;
c. flowing a gas including a H₂/N₂ gas mixture in the chamber, and
d. heating the substrate to a temperature between 500° C. and 1,200° C. inclusive.

38. The method of claim 37, wherein the 2D material layer comprises WSe₂ and the temperature is approximately 800° C.

39. The method of claim 1, wherein the 2D material layer comprises MoS₂ or WS₂ and the step of using metal oxide chemical vapor deposition includes the steps of:
a. introducing M(NtBu)₂(dpamd)₂, where M is either molybdenum or tungsten, into a chamber containing the substrate;
b. introducing elemental sulfur (S₈) into the chamber;
c. flowing a gas in the chamber, and
d. heating the substrate to a temperature between 500° C. and 1,000° C. inclusive.

40. The method of claim 39, wherein the 2D material layer comprises WS₂ and the temperature is approximately 800° C.

41. The method of claim 1, wherein the 2D material layer comprises boron nitride and the step of using metal oxide chemical vapor deposition includes the steps of:
a. introducing triethylboron (TEB, (C2H5)3B)) and ammonia (NH3) into a chamber containing the substrate;
b. flowing a gas in the chamber; and
c. heating the substrate to a temperature between 700° C. and 1500° C. inclusive.

42. The method of claim 41, wherein the temperature is approximately 1280° C.
